(19) United States
(12) Patent Application Publication
(10) Pub. No.: US 2010/0175756 A1
(43) Pub. Date: Jul. 15, 2010

(54) Method For Bonding Of Concentrating Photovoltaic Receiver Module To Heat Sink Using Foil And Solder

(76) Inventors: Timothy P. Weihs, Baltimore, MD (US); Zhaojuan He, Ellicott City, MD (US); David Van Heerden, Baltimore, MD (US)

Correspondence Address: Polster, Lieder, Woodruff & Lucchesi, L.C., 12412 Powerscourt Dr. Suite 200, St. Louis, MO, 63131-3615, US

(21) Appl. No.: 12/687,933

(22) Filed: Jan. 15, 2010

Related U.S. Application Data
(60) Provisional application No. 61/144,876, filed on Jan. 15, 2009.

(51) Int. Cl. H01L 31/04; B32B 37/12

(52) U.S. Cl. 136/259; 156/60

(57) ABSTRACT

A method for bonding a concentrating photovoltaic receiver module to a heat sink using a reactive multilayer foil as a local heat source, together with layers of solder, to provide a high thermal conductivity interface with long term reliability and ease of assembly.

### CROSS-REFERENCE TO RELATED APPLICATIONS

The present application is related to, and claims priority from, U.S. Provisional Patent Application Ser. No. 61/144,876 filed on Jan. 15, 2009, which is herein incorporated by reference.

### STATEMENT REGARDING FEDERALLY SPONSORED RESEARCH

Not Applicable.

### BACKGROUND OF THE INVENTION

The present invention is related generally to methods for bonding concentrating photovoltaic (CPV) receiver modules to heat sinks, and in particular, to a method for bonding a CPV receiver module to a heat sink with a reactive composite foil and solder at the bond interface.

Concentrating photovoltaic (CPV) modules are used to concentrate sunlight onto high-efficiency solar cells for the purpose of electrical power production. The solar cells are typically mounted onto substrates called receivers, and groups of the receiver modules are mounted onto heat sinks to maintain low solar cell junction temperatures and to achieve correspondingly high electrical conversion efficiencies.

Current CPV systems have developed power levels up to 2000 suns. The systems require highly efficient cooling methods to maintain low temperatures in the solar cells. The thermal interface between the CPV and its heat sink is a critical aspect in the transfer of heat generated by the CPV cells into heat sinks. The materials and bonding methods employed when forming the receiver modules have a direct impact on the cell performance, efficiency, and operational life. Typically thermal adhesives and pastes are used at the interface between CPV receiver modules and heat sinks. Both of these materials and bonding methods have disadvantages which fail to meet the thermal requirements of a CPV system rated for a power level at or above 2000 suns.

Thermal adhesives and pastes typically create an interface with thermal resistance of 20 Kmm²/W. At rated power levels equal to or exceeding 2000 suns, the waste heat which needs to be transferred from the cell to the heat sink through the interface can reach or exceed 140 W. A large thermal resistance for the interface will generate large temperature differences across the interface and will make it difficult to keep the solar cells running at temperatures below those that are required to avoid thermal destruction of the cell.

These adhesives and pastes are normally based on silicone materials, which require about 0.5-1.0 hours at elevated temperatures to cure. The curing process increases the production time and reduces the production output. The materials remain soft after curing and are not desirable for long term reliability and longevity of photovoltaic systems.

Adhesive or grease bonds degrade due to exposure to environment; the resulting degradation will increase the cell junction temperature and therefore will reduce the cell electrical conversion efficiency and cell longevity.

Given the limitations of the current interface material and bonding methods, there is a need for a novel material that can provide a high thermal conductivity interface with long term reliability and easy assembly process.

### BRIEF SUMMARY OF THE INVENTION

Briefly stated, the present disclosure provides a method for bonding a CPVB receiver module to a heat sink using a reactive multilayer foil as a local heat source, together with a solder, to provide a high thermal conductivity interface with long term reliability and ease of assembly.

In alternate embodiments, the present disclosure further provides a method for of bonding polymers or composites, as well as dissimilar materials that cannot be easily bonded by welding, brazing, or diffusion bonding. The present invention can result in reduction in machining time and costs either before or after bonding, and will result in lower thermal resistances for a given interface, compared to conventional thermal interface materials and methods.

### BRIEF DESCRIPTION OF THE SEVERAL VIEWS OF THE DRAWINGS

FIG. 1 is a sectional illustration of a CPV receiver module prior to bonding to a heat sink;

FIG. 2 is a sectional illustration of the CPV receiver module and heat sink of FIG. 1, arranged with a reactive foil and solder layers for bonding; and

FIG. 3 is a sectional illustration of the CPV receiver module and heat sink of FIGS. 1 and 2 after bonding.

### DETAILED DESCRIPTION

The following detailed description illustrates the invention by way of example and not by way of limitation. The description enables one skilled in the art to make and use the present disclosure, and describes several embodiments, adaptations, variations, alternatives, and uses of the present disclosure, including what is presently believed to be the best mode of carrying out the present disclosure.

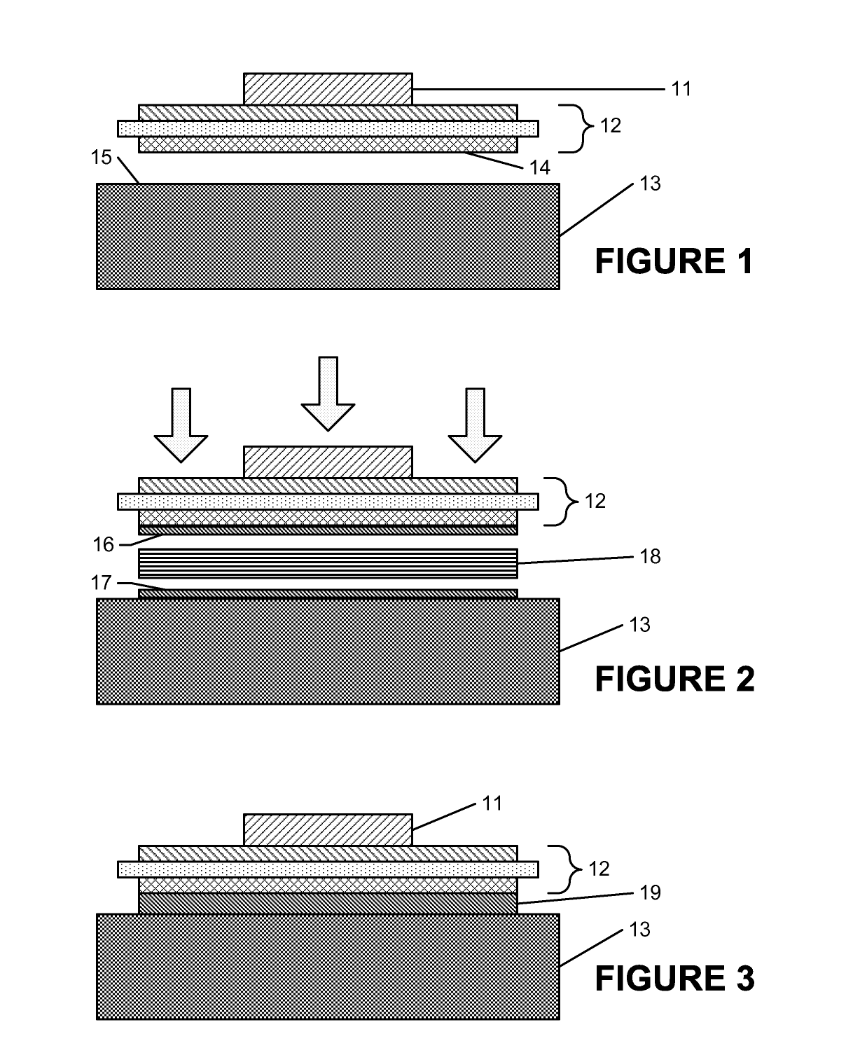

In a first embodiment, shown schematically in FIGS. 1-3, a receiver module (solar cell substrate—Cu/ceramic/Cu board—PCB, Al, etc.) 12 with a CPV cell (solar cell die(s) Si, Ge, compound semiconductor) 11 mounted on the top, is positioned to be bonded to a heat sink (Al, Cu or composite) 13 using a reactive composite joining process with a reactive multilayer foil 18 and solder layers 16 and 17 to form a bond 19. Reactive multilayer foils 18 and their related composite joining processes have been described in several patents including U.S. Patent Application Publication No. 2008/0063889 A1 to Duckham, et al., filed Sep. 3, 2007 as U.S. patent application Ser. No. 11/851,003, which is incorporated herein by reference.

As seen best in FIG. 2, the faying surface 14 of the receiver module 12 and the faying surface 15 of heat sink are pre-wet with layers 16 and 17 of solder alloy by suitable means known in the art, such as, but not limited to, application of solder with a hot plate or the screen printing of solder. Methods of solder application are described in U.S. patent application Ser. No. 11/851,003, which is herein incorporated by reference. The surfaces of the solder alloy 16 on the receiver module and the solder alloy 17 on the heat sink are aligned parallel to each other to within one part in 1000 by machining or other suitable alignment means known in the art.

Once the solder layers 16 and 17 are disposed and aligned, one or more pieces of a reactive multilayer foil 18 are placed between the layer 16 of solder alloy and layer 17 of solder alloy, and a pressure is applied perpendicular to the aligned components to hold the faying surfaces 14 and 15 against the reactive multilayer foil pieces 18, as shown in FIG. 2. The foil pieces 18 are then ignited by a suitable application of initiation energy and the resulting exothermic reaction in the reactive multilayer foil 18 melts a quantity of the solder alloy layers 16 and 17 sufficient to cause wetting and bonding between the faying surfaces. When the solder alloy solidifies, the receiver module 12 and heat sink 13 are bonded together by a bond layer 19 of solder material infused with the remnants of the reactive multilayer foil, as shown in FIG. 3.

The reactive multilayer foils 18 utilized in the reactive composite joining methods of the present disclosure are typically formed by magnetron sputtering and consist of thousands of alternating nanoscale layers of materials, such as nickel and aluminum. The layers react exothermically when atomic diffusion between the layers is initiated by an external energy pulse, and release a rapid burst of heat in a self-propagating reaction. If the reactive multilayer foils 18 are sandwiched between layers of a bonding material or fusible material, such as the solder alloy layers 16 and 17, the heat released by the exothermic reaction of the reactive multilayer foils 18 can be harnessed to melt these layers of bonding material. The resulting bonding layer 19 comprises a solder layer that includes the reaction products of the reactive multilayer foil. By controlling the properties of the reactive multilayer foils 18, the amount of heat released by the reactive multilayer foils 18 during the exothermic reaction can be tuned to ensure there is sufficient heat to melt the fusible material layers 16 and 17, but at the same time maintain the bulk of the adjacent components 11, 12, and 13 at or close to room temperature. Further details concerning reactive multilayer foils 18, joining with them, and their reaction products can be found in U.S. Pat. No. 6,736,942, which is incorporated herein by reference.

In related embodiments, the solder alloy may be applied to the faying surfaces 14 and 15 of one or both components via a thermal spray method. Any of a variety of thermal spray methods known in the art may be used, including flame spraying, arc spraying, plasma spraying, detonation spraying, high velocity oxy-fuel (HVOF) spraying, laser spraying and cold spraying. The advantage of thermally spraying a layer of solder 16 or 17 is that the component onto which the solder is deposited is not heated as much as in conventional pre-tinning, pre-soldering or pre-brazing methods that require the component to be heated above the melting temperature of the solder or braze. These thermal spray methods work best for metal components which can be grit blasted prior to spraying to improve the adhesion between the solder layer and the component surface. Thermal spray methods may also be used to apply a fusible layer to a component made of a ceramic or a polymer matrix composite.

In another embodiment a solder alloy is applied to the faying surfaces 14 and 15 using a screen printing method. Such a method is commonly used in microelectronics manufacturing and can enable the deposition of 50 microns or more of solder paste onto a solar cell substrate without damaging the solar cell 12 that is attached to the substrate. It can also be used to apply a solder paste to a heat sink 13.

As an alternative to pre-wetting the components with a solder layer 16 or 17, the faying surfaces 14 and 15 of the components 12 and 13 may be metallized by methods known in the art, such as physical vapor deposition. The object of the metallization process is to produce a faying surface 14 or 15 that may be easily wet by molten solder during the instant that the solder is molten in the reactive composite joining process. The metallization layer may be a noble metal such as gold or silver or a very thin layer of solder such as tin, or a thin layer of braze such as Incusil®. Metallization may also be carried out via electroplating or chemical (electroless) plating, or immersion (chemical) plated, for instance with tin, nickel and gold.

If more solder is present in the resulting bond layer 19, the thickness of the layers 16 and 17 that are pre-adhered on each component may be as thick as 100 μm. The maximum thickness of any pre-wet layer is dictated by the constraints of the application method or the desired properties of the resulting bond.

Solder thickness at the interface requires optimization to meet both the thermal performance and reliability performance requirements. As the solder thickness in the resulting bond layer 19 increases, thermal performance of the interface decreases as the thermal resistance increases but reliability performance such as temperature cycling performance is improved. Thus, there is a tradeoff between the thermal performance and reliability performance. In one embodiment of the present disclosure, the bond layer 19 of the receiver module 12 to heat sink 13 with a layer of multilayer foil 18 and 50 μm thick solder at the bond layer interface showed good bonding quality and thermal performance, however, the bond cracked after 100 cycles of temperature range −40 C to 125 C. With thicker solder layers 19 at the bonding interface, to accommodate the thermal stress caused by CTE mismatch between two components during temperature cycling, the bonds could survive up to 500 cycles without obvious degradation at the interfaces. Tests show the solder thickness of 200 μm to 500 μm provides good thermal performance with positive temperature cycling results for applications involving bonding a CPVB receiver module 12 to a heat sink 13.

In another embodiment, a freestanding solder preform such as tin solder may be applied to the faying surfaces 14 and 15 of one or both components 12, 13.

In another embodiment, the two surfaces of the reactive multilayer foil 18 which are facing the components 12, 13 are electroplated or coated by other means known in the art with a layer of tin or other fusible alloy, replacing the need to apply layers of solder onto the faying surfaces 14 and 15. The maximum tin layer thickness is limited by the heat produced by the reactive multilayer foil and the thermal characteristics of the bond and components. The layer must be thin enough so that all the tin melts during the joining reaction. For a Ni—Al reactive multilayer foil 60 μm thick, the tin on each surface may be up to about 25 μm thick if the components are thermally conductive metals.

The following examples are illustrative of the use of the methods of the present disclosure, but are not intended to limit the present disclosure in any way. Those of ordinary skill in the art will recognize the wider application so of the methods of the present disclosure beyond the specific examples set forth herein.

### Example 1

A heat sink 13 is placed on a hot plate, and a layer of tin solder 17 is applied on the faying (joining) surface 15. The heat sink 13 is then cooled and the tin solder 17 is machined flat to a thickness of 200 μm. The faying surface of receiver module 12 is electroplated with tin to a thickness of 100 μm. A single piece 18 of Ni—Al reactive multilayer foil 60 μm thick is cut to the shape of the bond area (14, 15) and placed between the faying surfaces 14, 15 of the receiver module 12 and heat sink 13. A compliant layer and an aluminum spacer 1.25″ (3.2 cm) thick are placed above the receiver module. A pressure of 200 psi (1.4 MPa) is applied to urge the faying surfaces 14, 15 together. The reactive multilayer foil piece 18 is ignited at an edge and reacts across the bond area to melt a fraction of the solder layers 16 and 17. When the solder 16 and 17 solidify, the receiver module 12 and heat sink 13 are bonded together. The reactive multilayer foil piece 18 may consist of more than one piece of foil, laterally adjacently arranged to cover the surface of the entire bond area.

### Example 2

In a second example, both the faying surfaces 14 and 15 of the receiver substrate 12 and heat sink 13 are grit-blasted to a surface finish of between 120 and 800 μin (3-20 μm). The faying surfaces 14, 15 are then coated with a layer of tin 500 μm thick using wire arc spray. The tin layer is subsequently machined to a thickness of 150 μm on each component. A single piece 18 of Ni—Al reactive multilayer reactive foil 60 μm thick is cut to the shape of the bond area and placed between the faying surfaces 14, 15 of the receiver module 12 and heat sink 13. A pressure of 200 psi (1.4 MPa) is applied to urge the faying surfaces 14, 15 together. The reactive multilayer foil piece 18 is ignited at an edge and reacts across the bond area to melt a fraction of the solder. When the solder solidifies, the receiver module and heat sink are bonded together.

Example 3

In a third example, the faying surface 15 of heat sink 13 is grit-blasted to a surface finish of between 120 and 800 μin (3-20 μm). The faying surface 15 is then coated with a layer of tin 500 μm thick using wire arc spray. The tin layer is then machined to a thickness of 250 μm. The faying surface 14 of the receiver module 12 is electroplated with tin to a thickness of 25 μm. A single tin solder perform 16, 25 μm thick, and a single Ni—Al reactive multilayer foil 18 which is 80 μm thick are cut to the shape of the bond area and placed between the faying surfaces 14 and 15 of the receiver module 12 and heat sink 13 with tin solder perform 16 adjacent the faying surface 14 of the receiver module 12. A pressure of 600 psi (4.1 MPa) is applied to urge the faying surfaces 14 and 15 together. The reactive multilayer foil piece 18 is ignited at an edge and reacts across the bond area to melt a fraction of the solder. When the solder solidifies, the receiver module 12 and heat sink 13 are bonded together.

It can now be seen that in one aspect the present disclosure sets forth an improved method for bonding a concentrating photovoltaic receiver module 12 to a heat sink 13 utilizing a reactive multilayer foil 18. The resulting bond layer 19 is highly thermal conductive and durable. The assembly process is simplified and allows multiple receiver modules 12 to be assembled at one time. With the thermally conductive interface between receiver module 12 and heat sink 13, the heat transfer between solar cell 12 and heat sink 13 is more efficient, which allows the manufacturer to reduce the size of receiver module 12 without increasing the solar cell junction temperature and reducing the corresponding electrical conversion efficiency.

In an alternate embodiment, the present novel bonding method using a reactive multilayer foil 18 can be used to bond a solar cell die 11 to receiver module 12, or another electronic package to a substrate. In this case the solar cell die 11 is metalized on its backside and a solder perform is used. The receiver module 12 can be metalized or pre-tinned with a layer of solder, prior to bonding.

As various changes could be made in the above constructions without departing from the scope of the disclosure, it is intended that all matter contained in the above description or shown in the accompanying drawings shall be interpreted as illustrative and not in a limiting sense.

1. A concentrating photovoltaic system comprising:
at least a first component with at least one joining surface coated with a layer of a fusible material;
reaction remnants of a reactive composite material adhered to the layer of fusible material on the joining surface of the first component; and
at least a second component with at least one joining surface adhered to said reaction remnants of said reactive composite material.

2. The concentrating photovoltaic system of claim 1 wherein said first component is a receiver, wherein said second component is a heat sink, and wherein said reaction remnants of said reactive composite material adhered to said joining surfaces define a bond layer.

3. The concentrating receiver module and heat sink of claim 1 wherein the bonding region comprises a fusible material.

4. The concentrating photovoltaic system of claim 1 wherein said at least a first component is a non-metal composite; and wherein said fusible material is a metal or metal alloy.

5. The concentrating photovoltaic system of claim 1 wherein said first component joining surface has an average roughness between 3 and 20 μm.

6. A method for bonding a photovoltaic receiver module to a heat sink comprising the steps of:
providing a first and at least one second component, each with a facing faying surface;
disposing a layer of fusible material adjacent to the faying surface of each component;
disposing a reactive composite material between the layers of fusible material associated with each faying surface;
applying pressure on the reactive composite material through the component bodies to urge the faying surfaces together; and
initiating an exothermic reaction in the reactive composite material, said exothermic reaction fusing said layers of fusible material to form a bond between the faying surfaces of the first component and the at least one additional component body.

7. The method of claim 6 wherein the faying surface of at least one of the components is metallized.

8. An assembly comprising:
a heat sink with a faying surface;
a photovoltaic receiver module with a faying surface substantially mirroring the faying surface of the heat sink; and
a reactive multilayer foil preform comprising at least one piece of reactive multilayer foil interposed between the faying surface of the heat sink and the faying surface of the receiver module.

9. The assembly of claim 8 wherein at least one faying surface is coated with a fusible alloy.

10. The assembly of claim 8 wherein the reactive multilayer foil preform is coated with a fusible alloy.
